(19) United States
(12) Patent Application Publication
(10) Pub. No.: US 2015/0145123 A1
(43) Pub. Date: May 28, 2015

(54) POWER SEMICONDUCTOR MODULE AND METHOD OF MANUFACTURING THE SAME

(71) Applicant: SAMSUNG ELECTRO-MECHANICS CO., LTD., Suwon-Si (KR)

(72) Inventor: Job Ha, Suwon-Si (KR)

(73) Assignee: SAMSUNG ELECTRO-MECHANICS CO., LTD., Suwon-si (KR)

(21) Appl. No.: 14/314,826

(22) Filed: Jun. 25, 2014

(30) Foreign Application Priority Data
Nov. 25, 2013 (KR) 10-2013-0143941

(51) Int. Cl. H01L 23/498; H01L 21/48; H01L 21/56; H01L 23/31

(52) U.S. Cl. CPC H01L 23/49811; H01L 23/3114; H01L 21/4853; H01L 21/565
USPC 257/737; 438/126

(57) ABSTRACT

Disclosed herein are a power semiconductor module and a method of manufacturing the same. The power semiconductor module includes: a substrate on which a semiconductor device is mounted; a pin positioned on the substrate and having one side electrically connected to the substrate; and a molding part formed to cover a portion of the pin and the substrate and the semiconductor device, wherein the molding part has a pin insertion opening.

### CROSS REFERENCE TO RELATED APPLICATION

This application claims the benefit of Korean Patent Application No. 10-2013-0143941, filed on Nov. 25, 2013, entitled “Power Semiconductor Module and Method of Manufacturing the Same”, which is hereby incorporated by reference in its entirety into this application.

### BACKGROUND OF THE INVENTION

1. Technical Field

The present invention relates to a power semiconductor module and a method of manufacturing the same.

2. Description of the Related Art

Energy efficiency regulations have triggered great interest in power conversion and energy efficiency. Power semiconductor modules are increasingly required to be miniaturized and have a high level of heat dissipation, high reliability, and the like, to meet the demand in the markets, as well as maximizing power conversion efficiency. Recently, as power semiconductor modules have been variously applied, needs for power semiconductor modules in respect of ratings and forms have been diversified. For example, products of 1200V to 100A require high insulating characteristics and heat dissipation characteristics, rather than low power consumption; however, since sizes of devices mounted therein are very small, relative to large power products, there is no need to adopt a housing structure incurring high package costs if a heat dissipation substrate is appropriately considered. Thus, to meet various requirements, a power semiconductor module having a new structure considering electrical connections, heat dissipation design, structure design, and the like, as well as securing a power semiconductor element having stable characteristics needs to be developed.

### PRIOR ART DOCUMENT

(Patent Document 1) Japanese Patent Laid-Open Publication No. 2002-315357

### SUMMARY OF THE INVENTION

The present invention has been made in an effort to provide a power semiconductor module in which pins for external connection are formed on a substrate to reduce a size and enhance reliability.

According to an embodiment of the present invention, there is provided a power semiconductor module including: a substrate on which a semiconductor device is mounted; a pin positioned on the substrate and having one side electrically connected to the substrate; and a molding part formed to cover a portion of the pin and the substrate and the semiconductor device, wherein the molding part has a pin insertion opening.

The substrate may include a connection pad.

The pin may have one side and the other side, and the one side may be disposed in the molding part and the other side may be protruded from the molding part.

The power semiconductor module may further include a sleeve formed to allow one side of the pin to be inserted therein.

The power semiconductor module may further include a solder interposed between the pin and the substrate.

The power semiconductor module may further include a wire electrically connecting the semiconductor device and the substrate.

The power semiconductor module may further include: an insulating material filling the pin insertion opening.

A diameter of the pin insertion opening may be greater than that of the pin.

According to another embodiment of the present invention, there is provided a method of manufacturing a power semiconductor module, including: preparing a substrate with a semiconductor device mounted thereon; forming a mold in the substrate; injecting a molding material to the interior of the mold; removing the mold to form a molding part; forming a pin insertion opening in the molding part; and bonding the pin to the substrate so as to be inserted into the opening.

The method may further include: forming a solder in the pin insertion opening before the bonding of the pin to the substrate.

In the forming of the pin insertion opening, an opening may be processed by using a laser.

The forming of the molding part may include: forming a mold having a protrusion; injecting a molding material into the mold; and removing the mold having the protrusion to form a molding part having a pin insertion opening.

The method may further include: connecting the semiconductor device to the substrate by a wire, after the preparing of the substrate with the semiconductor device mounted thereon.

The substrate may include a connection pad.

The pin may have one side and the other side, and the one side may be disposed in the interior of the molding part and the other side may be protruded from the molding part.

The method may further include forming a sleeve allowing one side of the pin to be inserted therein, in the pin insertion opening, after the forming a pin insertion opening in the molding part.

The method may further include: filling the pin insertion opening with an insulating material.

A diameter of the pin insertion opening may be greater than that of the pin.

### BRIEF DESCRIPTION OF THE DRAWINGS

The above and other objects, features, and advantages of the present invention will be more clearly understood from the following detailed description taken in conjunction with the accompanying drawings, in which:

FIGS. 1 and 2 are cross-sectional views illustrating a power semiconductor module according to an embodiment of the present invention;

FIGS. 3 through 10 are cross-sectional views illustrating sequential processes of a method of manufacturing a power semiconductor module according to another embodiment of the present invention; and

FIGS. 11 through 18 are cross-sectional views illustrating sequential processes of a method of manufacturing a power semiconductor module according to another embodiment of the present invention.

### DESCRIPTION OF THE PREFERRED EMBODIMENTS

The objects, features, and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side”, and the like, are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

Power Semiconductor Module

### First Embodiment

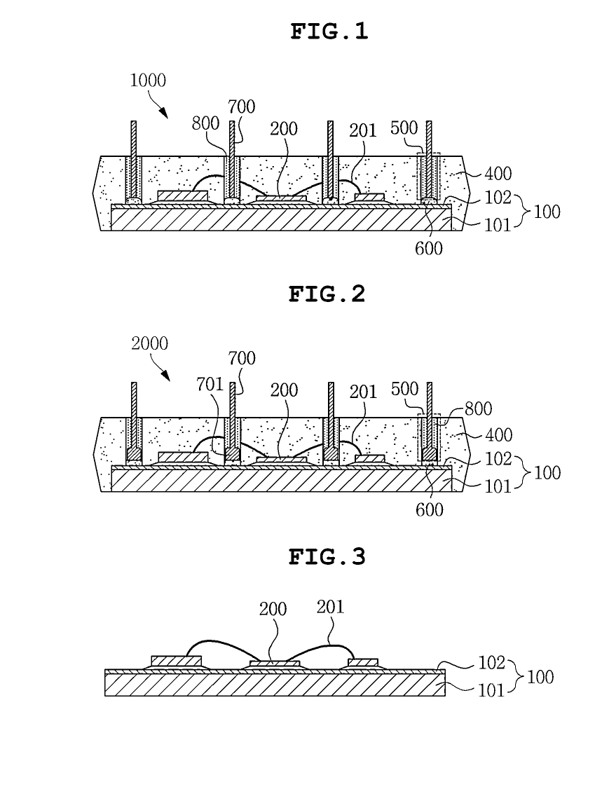

FIG. 1 is a cross-sectional view illustrating a power semiconductor module according to a first embodiment of the present invention.

As illustrated in FIG. 1, a power semiconductor module 1000 according to the first embodiment of the present invention includes a substrate 100 on which a plurality of semiconductor devices 200 are mounted, pins 700 positioned on the substrate 100 and having one side electrically connected to the substrate 100, and a molding part 400 formed to cover the substrate 100 and the plurality of semiconductor devices 200. The molding part 400 has a pin insertion opening 500.

The substrate 100 is a circuit board including one or more layers of circuits including a connection pad 102 on an insulating layer. Preferably, the substrate 100 may be a printed circuit board (PCB). In FIG. 1, for the description purposes, a specific inner-layer circuit configuration is omitted but a person skilled in the art may easily recognize that a general circuit board will be applied.

Here, a resin insulating layer may be used as an insulating layer of the substrate 100. The resin insulating layer may be formed of a thermosetting resin such as an epoxy resin, a thermoplastic resin such as polyimide, a resin, e.g., prepreg, obtained by impregnating any of the foregoing resins with a reinforcement agent such as glass fiber or an inorganic filler, or a photocurable resin, or the like, but the present invention is not particularly limited thereto.

Also, the substrate 100 may be a ceramic substrate.

The ceramic substrate may be formed of a metal-based nitride or a ceramic material. The metal-based nitride may include, for example, an aluminum nitride (AlN) or a silicon nitride (SiN), and the ceramic material may include an aluminum oxide (Al₂O₃) or a beryllium oxide (BeO), but the present invention is not particularly limited thereto.

Although not shown, a conductive epoxy may be used as a bonding member between the substrate 100 and the semiconductor devices 200, but the present invention is not particularly limited thereto. Here, preferably, a bonding member having high thermal conductivity may be used to effectively dissipate heat.

Each semiconductor device 200 may include a power element and a control element, but the present invention is not limited thereto. For example, the power element may be an element having a high heating value, such as an insulated gate bipolar transistor (IGBT), a diode, or the like, and the control element is an element having a small heating value, such as a control integrated circuit (IC).

In FIG. 1, each semiconductor device 200 is schematically illustrated, omitting specific elements thereof, but a person skilled in the art may easily recognize that the semiconductor device 200 having any structure known in the art may be applied without being particularly limited.

Also, wires 201 may be formed to electrically connect the plurality of semiconductor devices 200. The wires 201 may be formed of aluminum (Al), gold (Au), copper (Cu), and the like, but the present invention is not particularly limited thereto. In general, aluminum (Al) may be used as a material of a wire applying a high rated voltage, as a semiconductor component, a power device.

The molding part 400 is formed to fill the spaces above the substrate 100, reducing a problem such as delamination, or the like, between the substrate 100 and a molding member, and thus, reliability may be enhanced. Also, since the formation of the molding part 400 blocks heat, a heat dissipation effect may be further enhanced.

In this case, the molding part 400 may be formed of silicon gel, an epoxy molded compound, or the like, but the present invention is not particularly limited thereto.

Here, the molding part 400 may have the pin insertion opening 500, and one side of the pin 700 may be bonded to be electrically connected to the substrate 100 through the opening 500.

Here, the one side of the pin 700 may be bonded to the substrate 100 by solder 600.

A diameter of the pin insertion opening 500 may be greater than that of each pin 700.

Here, the pin 700 may have one side and the other side. One side of the pin 700 may be defined as the pin 700 formed within the molding part 400 and the other side thereof may be defined as the pin 700 formed to be protruded outwardly from the molding part 400.

The pin 700 may be formed in a position desired by a person skilled in the art. Here, by forming the pin 700 in the vicinity of the device, a terminal connected to the outside may be obtained in the vicinity of the device, increasing a degree of freedom in designing the device and the pin.

Thus, the module may easily perform routing.

Also, a size of the module may be reduced.

### Second Embodiment

FIG. 2 is a cross-sectional view illustrating a power semiconductor module according to a second embodiment of the present invention.

In describing the second embodiment, descriptions of components identical to those of the first embodiment will be omitted and differences of the second embodiment will be described.

As illustrated in FIG. 2, a power semiconductor module 2000 according to the second embodiment of the present invention includes a substrate 100 on which a plurality of semiconductor devices 200 are mounted, pins 700 positioned on the substrate 100 and having one side electrically connected to the substrate 100, and a molding part 400 formed to cover portions of the pins 700, the substrate 100, and the plurality of semiconductor devices 200. The molding part 400 has a pin-insertion opening 500.

In this case, one side of each pin 700 may be inserted into a sleeve 701.

The molding part 400 may have the pin insertion opening 500, and the sleeve 701 with the pin 700 inserted therein may be bonded to the substrate 100 through the opening 500 so as to be electrically connected thereto.

In this case, solder 600 may be interposed between a lower surface of the sleeve 701 with the pin 700 inserted therein and the substrate 100.

A diameter of the pin insertion opening 500 may be greater than that of the pin 700, and may correspond to a diameter of the sleeve 701.

In the present exemplary embodiment, regions of the pin insertion opening 500, other than the pin 700 and the sleeve 701 regions, are filled with an insulating material 800, but the regions may not be filled as needed.

The insulating material 800 may be a material identical to that of the molding part 400, but the present invention is not particularly limited thereto

Here, the pin 700 having one side inserted into the sleeve 701 may be formed in a position desired by a person skilled in the art. Here, by forming the pin 700 in the vicinity of the device, a terminal connected to the outside may be obtained in the vicinity of the device, increasing a degree of freedom in designing the device and the pin.

Thus, the module may easily perform routing.

Also, a size of the module may be reduced.

In the present embodiment, since the sleeve 701 is soldered to the substrate 100, a solder bonding area may be increased, relative to the case of soldering the pin 70 directly to the substrate 100, thereby enhancing reliability.

Method of Manufacturing Power Semiconductor Module

FIGS. 3 through 10 are cross-sectional views illustrating sequential processes of a method of manufacturing a power semiconductor module according to another embodiment of the present invention.

As illustrated in FIG. 3, a substrate 100 with a plurality of semiconductor devices 200 mounted thereon is prepared.

Here, the substrate 100 may include a connection pad 102.

The substrate 100 is a circuit board including one or more layers of circuits including a connection pad 102 on an insulating layer. Preferably, the substrate 100 may be a printed circuit board (PCB). In FIG. 1, for the description purposes, a specific inner-layer circuit configuration is omitted but a person skilled in the art may easily recognize that a general circuit board will be applied.

Here, a resin insulating layer may be used as an insulating layer of the substrate 100. The resin insulating layer may be formed of a thermosetting resin such as an epoxy resin, a thermoplastic resin such as polyimide, or a resin, e.g., prepreg, obtained by impregnating any of the foregoing resins with a reinforcement agent such as glass fiber or an inorganic filler, or a photocurable resin, or the like, but the present invention is not particularly limited thereto.

Also, the substrate 100 may be a ceramic substrate.

The ceramic substrate may be formed of a metal-based nitride or a ceramic material. The metal-based nitride may include, for example, an aluminum nitride (AlN) or a silicon nitride (SiN), and the ceramic material may include an aluminum oxide (Al₂O₃) or a beryllium oxide (BeO), but the present invention is not particularly limited thereto.

In this case, a bonding member may be interposed between the substrate 100 and the semiconductor device 200 to bond them.

Here, the bonding member may be solder or a conductive epoxy, but the present invention is not particularly limited thereto and, in general, a bonding member having high thermal conductivity is used to effectively dissipate heat.

Each semiconductor device 200 may include a power element and a control element, but the present invention is not limited thereto. For example, the power element may be an element having a high heating value, such as an insulated gate bipolar transistor (IGBT), a diode, or the like, and the control element is an element having a small heating value, such as a control integrated circuit (IC).

In the drawing, each semiconductor device 200 is schematically illustrated, omitting specific elements thereof, but a person skilled in the art may easily recognize that the semiconductor device 200 having any structure known in the art may be applied without being particularly limited.

Also, wires 201 may be formed to electrically connect the plurality of semiconductor devices 200. The wires 201 may be formed of aluminum (Al), gold (Au), copper (Cu), and the like, but the present invention is not particularly limited thereto. In general, aluminum (Al) may be used as a material of a wire applying a high rated voltage, as a semiconductor component, a power device.

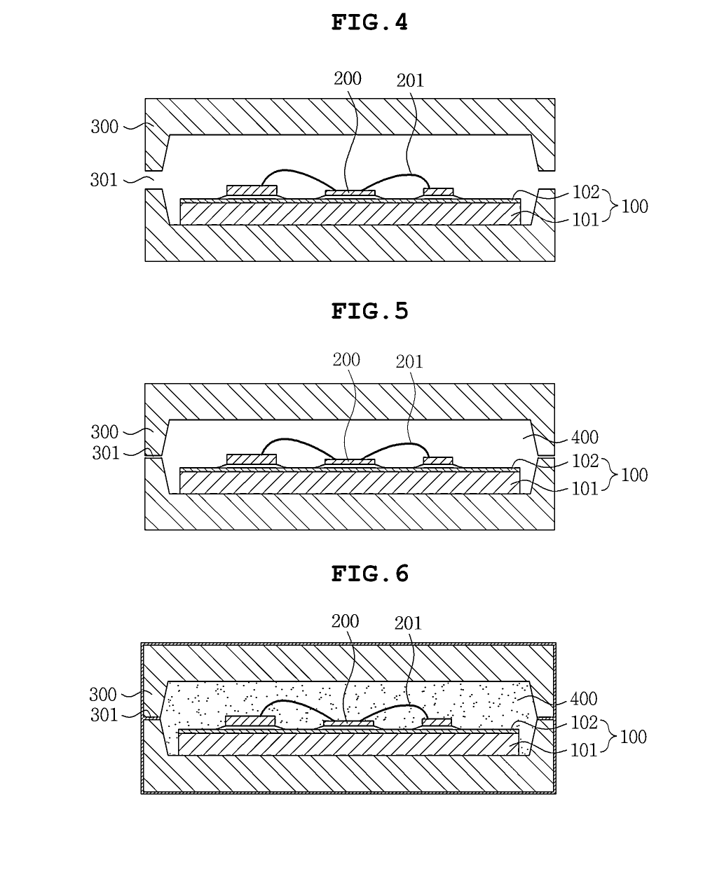

As illustrated in FIG. 4, a mold 300 may be installed in the substrate 100.

In this case, the mold 300 may have openings 301 formed in both sides thereof.

As illustrated in FIG. 5, a height of the mold 300 may be adjusted to correspond to a shape of a molding part to be formed later.

As illustrated in FIG. 6, a molding member may be injected through the openings 301 of the mold 300.

The molding member may be formed of a silicon gel, an epoxy molded compound, or the like, but the present invention is not particularly limited thereto.

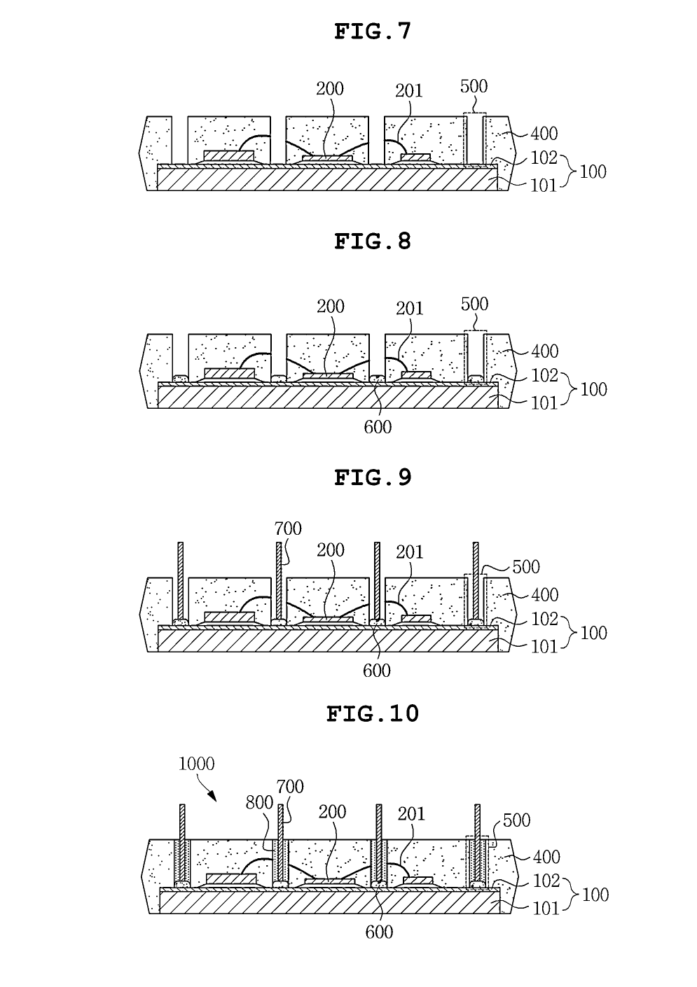

As illustrated in FIG. 7, the mold 300 may be removed to form a molding part 400.

A pin insertion opening 500 may be formed in the molding part 400.

In the present embodiment, the opening is formed by using a YAG laser or a CO₂ laser, but a method of forming the opening is not particularly limited.

The pin insertion opening 500 may be formed in a position corresponding to a position in which a pin is to be formed, and may be formed freely in a position desired by a person skilled in the art.

In this case, the pin insertion opening 500 may be formed not to be in contact with the wire 2012.

The molding part 400 is formed to fill the spaces above the substrate 100, reducing a problem such as delamination, or the like, between the substrate 100 and a molding member, and thus, reliability may be enhanced. Also, since the formation of the molding part 400 blocks heat, a heat dissipation effect may be further enhanced.

As illustrated in FIG. 8, the solder 600 may be formed in the pin insertion opening 500. Here, the solder 600 may also be formed on the connection pad 102.

As illustrated in FIG. 9, the pin 700 may be formed in the pin insertion opening 500 such that the pin 700 is bonded to the solder 600.

The pin 700 may be formed of a material conducting electricity flowing to serve as an external connection terminal. A diameter of the pin 700 may be smaller than that of the pin insertion opening 500.

Here, by forming the pin 700 in the vicinity of the device, a terminal connected to the outside may be obtained in the vicinity of the device, increasing a degree of freedom in designing the device and the pin.

Thus, the module may easily perform routing.

Also, a size of the module may be reduced.

Although not shown, one side of the pin 700 may be inserted into a sleeve 701.

The sleeve 701 with the pin 700 inserted therein may be formed in the pin insertion opening 500 so as to be bonded to the solder 600.

In this case, a diameter of the pin insertion opening 500 may be smaller than or correspond to that of the sleeve 701, and may be greater than that of the pin 700.

Accordingly, a solder bonding area may be increased, thereby enhancing reliability.

As illustrated in FIG. 10, a remaining region of the pin insertion opening 500, excluding the pin 700 region, may be filled with an insulating material.

The insulating material 800 may be a material identical to that of the molding part 400, but the present invention is not particularly limited thereto

Also, in the present embodiment, the pin insertion opening 500 is filled with the insulating material 800, but it may not be filled as needed.

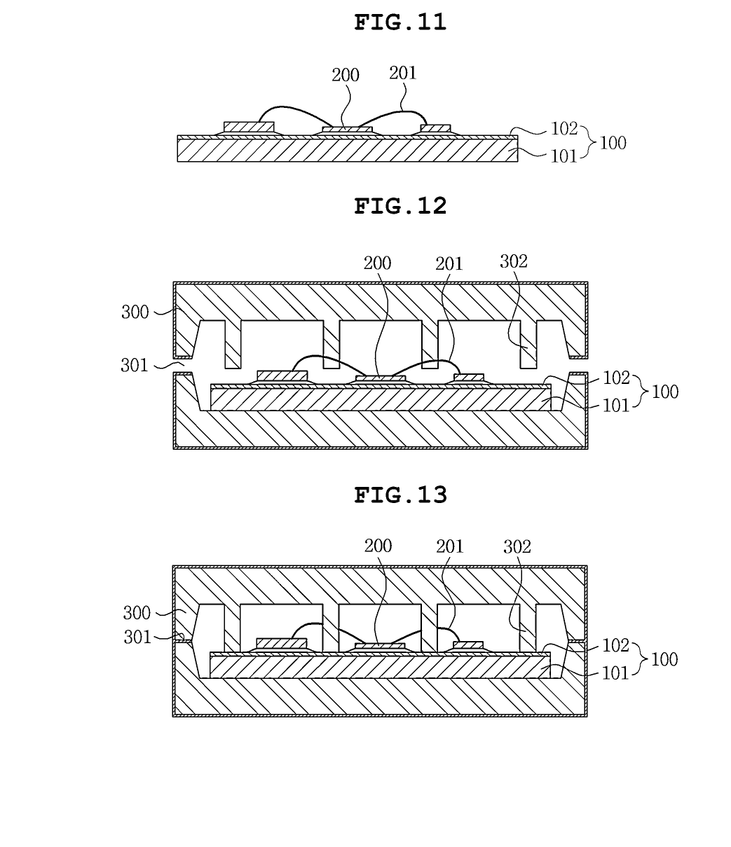

FIGS. 11 through 18 are cross-sectional views illustrating sequential processes of a method of manufacturing a power semiconductor module according to another embodiment of the present invention.

As illustrated in FIG. 11, a substrate on which a plurality of semiconductor devices 200 are mounted is prepared.

Here, the substrate 100 may include a connection pad 102.

The substrate 100 is a circuit board including one or more layers of circuits including a connection pad 102 on an insulating layer. Preferably, the substrate 100 may be a printed circuit board (PCB). In FIG. 1, for the description purposes, a specific inner-layer circuit configuration is omitted but a person skilled in the art may easily recognize that a general circuit board will be applied.

Here, a resin insulating layer may be used as an insulating layer of the substrate 100. The resin insulating layer may be formed of a thermosetting resin such as an epoxy resin, a thermoplastic resin such as polyimide, or a resin, e.g., prepreg, obtained by impregnating any of the foregoing resins with a reinforcement agent such as glass fiber or an inorganic filler, or a photocurable resin, or the like, but the present invention is not particularly limited thereto.

Also, the substrate 100 may be a ceramic substrate.

The ceramic substrate may be formed of a metal-based nitride or a ceramic material. The metal-based nitride may include, for example, an aluminum nitride (AlN) or a silicon nitride (SiN), and the ceramic material may include an aluminum oxide (Al₂O₃) or a beryllium oxide (BeO), but the present invention is not particularly limited thereto.

In this case, a bonding member may be interposed between the substrate 100 and the semiconductor device 200 to bond them.

Here, the bonding member may be solder or a conductive epoxy, but the present invention is not particularly limited thereto and, in general, a bonding member having high thermal conductivity is used to effectively dissipate heat.

Each semiconductor device 200 may include a power element and a control element, but the present invention is not limited thereto. For example, the power element may be an element having a high heating value, such as an insulated gate bipolar transistor (IGBT), a diode, or the like, and the control element is an element having a small heating value, such as a control integrated circuit (IC).

In the drawing, each semiconductor device 200 is schematically illustrated, omitting specific elements thereof, but a person skilled in the art may easily recognize that the semiconductor device 200 having any structure known in the art may be applied without being particularly limited.

Also, wires 201 may be formed to electrically connect the plurality of semiconductor devices 200. The wires 201 may be formed of aluminum (Al), gold (Au), copper (Cu), and the like, but the present invention is not particularly limited thereto. In general, aluminum (Al) may be used as a material of a wire applying a high rated voltage, as a semiconductor component, a power device.

As illustrated in FIG. 12, a mold 300 having protrusions 302 is prepared.

The protrusions 302 may be formed in positions corresponding to positions of pin insertion openings to be formed later, and may be freely formed in positions desired by a person skilled in the art.

The mold 300 may be installed in the substrate 100. In this case, the mold 300 may have openings 301 formed in both sides thereof.

As illustrated in FIG. 13, a height of the mold 300 may be adjusted to correspond to a shape of a molding part to be formed later. In this case, lower surfaces of the protrusions 302 may be in contact with the substrate 100.

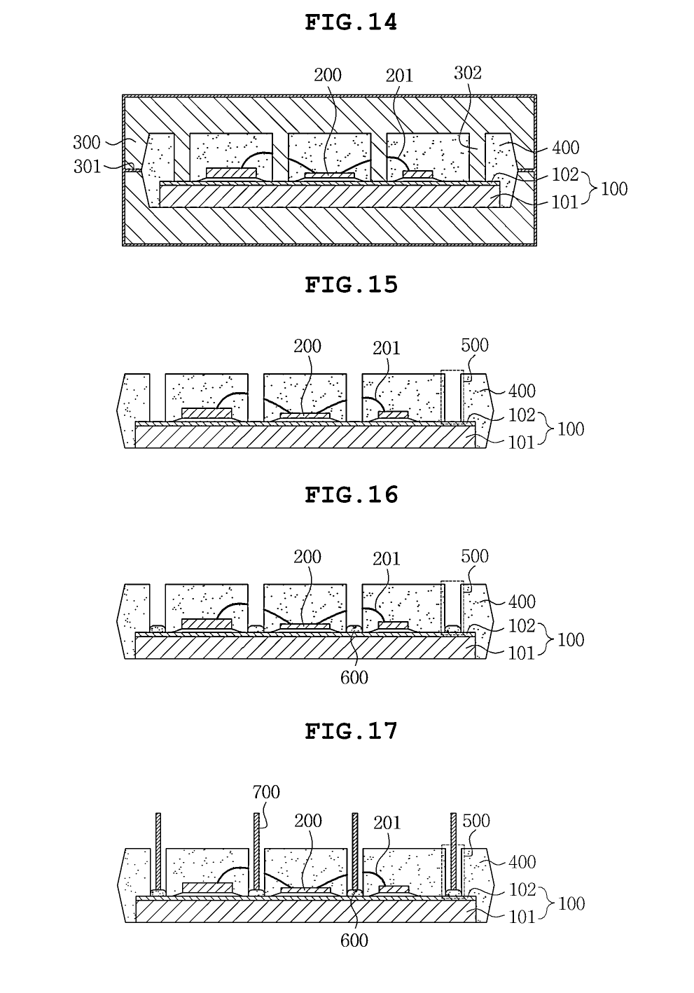

As illustrated in FIG. 14, a molding member may be injected through the openings 301 of the mold 300.

The molding member may be formed of a silicon gel, an epoxy molded compound, or the like, but the present invention is not particularly limited thereto.

As illustrated in FIG. 15, the mold 300 may be removed to form a molding part 400 having the pin insertion opening 500.

The molding part 400 is formed to fill the spaces above the substrate 100, reducing a problem such as delamination, or the like, between the substrate 100 and a molding member, and thus, reliability may be enhanced. Also, since the formation of the molding part 400 blocks heat, a heat dissipation effect may be further enhanced.

As illustrated in FIG. 16, the solder 600 may be formed in the pin insertion opening 500. Here, the solder 600 may also be formed on the connection pad 102.

As illustrated in FIG. 17, the pin 700 may be formed in the pin insertion opening 500 such that the pin 700 is bonded to the solder 600.

The pin 700 may be formed of a material conducting electricity flowing to serve as an external connection terminal. A diameter of the pin 700 may be smaller than that of the pin insertion opening 500.

Here, by forming the pin 700 in the vicinity of the device, a terminal connected to the outside may be obtained in the vicinity of the device, increasing a degree of freedom in designing the device and the pin.

Thus, the module may easily perform routing.

Also, a size of the module may be reduced.

Although not shown, one side of the pin 700 may be inserted into a sleeve (701 in FIG. 2).

The sleeve (701 in FIG. 2) with the pin 700 inserted therein may be formed in the pin insertion opening 500 so as to be bonded to the solder 600.

In this case, a diameter of the pin insertion opening 500 may be smaller than or correspond to that of the sleeve (701 in FIG. 2), and may be greater than that of the pin 700.

Accordingly, a solder bonding area may be increased, thereby enhancing reliability.

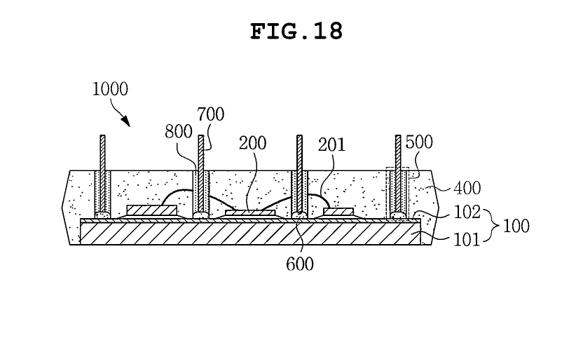

As illustrated in FIG. 18, a remaining region of the pin insertion opening 500, excluding the pin 700 region, may be filled with an insulating material.

The insulating material 800 may be a material identical to that of the molding part 400, but the present invention is not particularly limited thereto

Also, in the present embodiment, the pin insertion opening 500 is filled with the insulating material 800, but it may not be filled as needed.

According to the preferred embodiments of the present invention, by forming pins on a substrate in a power semiconductor module, a size of the module may be reduced. Also, since pins are formed in the vicinity of a device, a degree of freedom in disposing the device may be increased, and thus, the module may easily perform routing.

In another aspect, reliability of a solder bonding part of the pin may be enhanced, and when the pin is inserted into a sleeve so as to be applied, a solder bonding area may be increased.

Although the embodiments of the present invention have been disclosed for illustrative purposes, it will be appreciated that the present invention is not limited thereto, and those skilled in the art will appreciate that various modifications, additions, and substitutions are possible, without departing from the scope and spirit of the invention.

Accordingly, any and all modifications, variations, or equivalent arrangements should be considered to be within the scope of the invention, and the detailed scope of the invention will be disclosed by the accompanying claims.

What is claimed is:

1. A power semiconductor module comprising:
a substrate on which a semiconductor device is mounted;
a pin positioned on the substrate and having one side electrically connected to the substrate; and
a molding part formed to cover a portion of the pin and the substrate and the semiconductor device,
wherein the molding part has a pin insertion opening.

2. The power semiconductor module as set forth in claim 1, wherein the substrate includes a connection pad.

3. The power semiconductor module as set forth in claim 1, wherein the pin has one side and the other side, and the one side is disposed in the molding part and the other side is protruded from the molding part.

4. The power semiconductor module as set forth in claim 1, further comprising:
a sleeve formed to allow one side of the pin to be inserted therein.

5. The power semiconductor module as set forth in claim 1, further comprising a solder interposed between the pin and the substrate.

6. The power semiconductor module as set forth in claim 1, further comprising:
a wire electrically connecting the semiconductor device and the substrate.

7. The power semiconductor module as set forth in claim 1, further comprising:
an insulating material filling the pin insertion opening.

8. The power semiconductor module as set forth in claim 1, wherein a diameter of the pin insertion opening is greater than that of the pin.

9. A method of manufacturing a power semiconductor module, the method comprising:
preparing a substrate with a semiconductor device mounted thereon;
forming a mold in the substrate;
injecting a molding material to the interior of the mold;
removing the mold to form a molding part;
forming a pin insertion opening in the molding part; and
bonding the pin to the substrate so as to be inserted into the opening.

10. The method as set forth in claim 9, further comprising:
forming a solder in the pin insertion opening before the bonding of the pin to the substrate.

11. The method as set forth in claim 9, wherein, in the forming of the pin insertion opening, an opening is processed by using a laser.

12. The method as set forth in claim 9, wherein the forming of the molding part includes:
forming a mold having a protrusion;
injecting a molding material into the mold; and
removing the mold having the protrusion to form a molding part having a pin insertion opening.

13. The method as set forth in claim 9, further comprising:
connecting the semiconductor device to the substrate by a wire, after the preparing of the substrate with the semiconductor device mounted thereon.

14. The method as set forth in claim 9, wherein the substrate includes a connection pad.

15. The method as set forth in claim 9, wherein the pin has one side and the other side, and the one side is disposed in the molding part and the other side is protruded from the molding part.

16. The method as set forth in claim 9, further comprising forming a sleeve allowing one side of the pin to be inserted therein, in the pin insertion opening, after the forming a pin insertion opening in the molding part.

17. The method as set forth in claim 9, further comprising:
filling the pin insertion opening with an insulating material, after the bonding of the pin.

18. The method as set forth in claim 9, wherein a diameter of the pin insertion opening is greater than that of the pin.
